(19) United States
(12) Patent Application Publication
(10) Pub. No.: US 2021/0144226 A1
(43) Pub. Date: May 13, 2021

(54) PARTIAL DOWNLOADS OF COMPRESSED DATA

(71) Applicant: MICROSOFT TECHNOLOGY LICENSING, LLC, REDMOND, WA (US)

(72) Inventor: Miguel DE ICAZA AMOZURRUTIA, Brookline, MA (US)

(21) Appl. No.: 16/682,937

(22) Filed: Nov. 13, 2019

(51) Int. Cl. H04L 29/08; H04L 29/06

(52) U.S. Cl. CPC H04L 67/2828; H04L 69/04

(57) ABSTRACT

A client is able to decompress an internal portion of a compressed file on a server without having to download and decompress the part of the compressed file that precedes the internal portion. Initially, when the file is compressed, the state of the compressor, e.g., a dictionary, is periodically captured and stored in association with positions in the compressed file. A server stores the compressor states and positions in association with the compressed file. The client identifies the internal section of the compressed file to the server. The server selects a compressor state whose position is closest to the internal section. The server sends the client the selected compressor state and the internal portion of the compressed file. The client primes a decompressor with the sent compressor state, and the primed decompressor then decompresses the internal portion of the compressed file.

### BACKGROUND

Compression algorithms have long been used to compress data. Reducing data by compression can reduce storage hardware overhead, reduce network bandwidth consumption, increase the rate of information transfer, and so forth. Most efforts to improve compression have focused on compression efficiency, that is, how much a given unit data can be reduced in size. Efficient compression algorithms generally have a compressor state that controls how the uncompressed data is encoded (compressed). The compression state adapts as the uncompressed data is read and statistically analyzed. How data is compressed at any point depends on the compression of the data that preceded it as well as the compression algorithm.

Typically, the compressor state is a dictionary of associations between uncompressed strings and respectively corresponding codes. A compressed version of the uncompressed data is generated by statistical analysis and progressively building up a sequence of codes representing respective uncompressed strings. A compressed form of the uncompressed data will consist of codes in place of uncompressed words/strings. More sophisticated techniques and dictionaries exist, but most of them involve a dynamic compression state that maps uncompressed data to compressed data.

As observed only by the inventors, the dynamic compression/dictionary state of compression algorithms may be good for compression efficiency, but it makes it impossible to decompress and an interior portion of compressed data without first decompressing all of the data that precedes it. To do so, of course the compressed data must be available. Thus, compression algorithms that evolve with the data being compressed are problematic because all of the compressed data must be available and decompressed before a needed interior subset of the data can be decompressed. What precedes a needed portion must be decompressed in order to recreate the state and dictionaries required to decompress the needed portion. Depending on the application, this may require significant processing time, transmission bandwidth, storage space, etc.

An example of this problem can be seen with compressed packages that contain data items that are discrete units of data within the compressed data. A server might be providing, for download, a compressed package containing constituent files. A client might know which file it needs within the compressed package and might even be able to specify the location of the file within the compressed stream to the server. However, even if the server extracted only the relevant subset of compressed data that encompasses the constituent file, the client would not be able to decompress that subset without having all of the compressed file that preceded it.

Discussed below are techniques related to decompressing an internal section of compressed data without requiring decompression of all of the compressed data that preceded it.

### SUMMARY

The following summary is included only to introduce some concepts discussed in the Detailed Description below. This summary is not comprehensive and is not intended to delineate the scope of the claimed subject matter, which is set forth by the claims presented at the end.

A client is able to decompress an internal portion of a compressed file on a server without having to download and decompress the part of the compressed file that precedes the internal portion. This can be achieved either by having an off-line process record and capture the state of the compressor at discrete times during the compression, e.g., a dictionary, is periodically captured and stored in association with positions in the compressed file. A server stores the compressor states and positions in association with the compressed file. If the compressed file already exists then the compressor can process the uncompressed file to generate the compressor states without having to generate the compressed file. Alternatively, the server side can compute the state of the dictionary on demand when requested by a client. The client identifies the internal section of the compressed file to the server. The server selects a compressor state whose position is closest to the internal section; the compressor state can be a precomputed state or can be computed on demand by the server. The server sends the client the selected compressor state and the internal portion of the compressed file. The client primes a decompressor with the sent compressor state, and the primed decompressor then decompresses the internal portion of the compressed file.

Many of the attendant features will be explained below with reference to the following detailed description considered in connection with the accompanying drawings.

### BRIEF DESCRIPTION OF THE DRAWINGS

The present description will be better understood from the following detailed description read in light of the accompanying drawings, wherein like reference numerals are used to designate like parts in the accompanying description.

FIG. 1 shows a client downloading a compressed file from a server to obtain an internal section of the compressed file.

FIG. 2 shows how compression checkpoints can be captured while compressing an uncompressed file.

FIG. 3 shows a process for generating random access data.

FIG. 4 shows how the client and the server cooperate to enable the client to download and decompress a minimal amount of compressed file data to obtain a needed section.

FIG. 5 shows a client receiving an internal portion of a compressed file, an associated compressor state, and an offset.

FIG. 6 shows another embodiment for partial download and decompression.

FIG. 7 shows details of a computing device.

### DETAILED DESCRIPTION

FIG. 1 shows a client 100 downloading a compressed file 102 from a server 104 to obtain an internal section 106 of the compressed file 102. The section 106 is internal in that it is not at the beginning of the compressed file 102. For discussion, the sections or portions mentioned herein will be assumed to be internal.

Before the client 100 needs the section 106, the compressed file 102 was generated by a compressor 108 compressing an uncompressed file 110. The uncompressed file 110 is “uncompressed” with respect to the compressor 108; the data within the uncompressed file 110 could happen to have been previously compressed by another compressor. When the client 100 needs the section 106, the client performs process 111. That is, the client identifies the compressed file 102 to the server 104. The server 104 responds by providing the compressed file 102 to the client 100. The client 100 has a decompressor 112 that decompresses the compressed file 102 and outputs a decompressed file 114, which is equivalent to the uncompressed file 110. The client then extracts the needed section 106 from the decompressed file 114. Note that some decompressors can stop decompressing once the end of the section 106 has been decompressed. In any case, the client 100 at least needs all of the compressed file 102 that precedes the section 106 (referred to as the compressed prefix). As can be seen, a possibly sizeable compressed prefix may need to be downloaded and decompressed even though the data of the decompressed prefix is not needed by the client. The compressed prefix is needed to decompress the section 106. Compression may also be performed by an entity other than the server.

Still referring to FIG. 1, the terms “client” and “server” are labels to differentiate between any two entities exchanging compressed data as shown in FIG. 1. The client and server may be respective computing devices communicating over a communication link or network. The client and server might be services or entities in a compute cloud. The client and server could also be components executing on a same device, for instance virtual machines or containers. For discussion, the client will be assumed to be using an application-level protocol suitable for transferring files (e.g., hypertext transfer protocol) over a network from the server.

For convenience, a single server is described herein as performing various actions and providing various information. In practice, the actions and information may be handled by several cooperating server-side computing devices. A first server device may store an uncompressed file, a second server device may generate compressor state data by processing the uncompressed file at the first server device, and a third server device may serve out the compressor state and compressed data to client devices. The uncompressed file, the compressed file, and the compressor state may be on respective devices. The compressed data and the compressor state can be distributed by a content distribution network (CDN). The CDN may be a peer-to-peer network where peers both distribute and consume the compressed data and compressor state. Where a single “server” is referred to herein, these multi-device architectural variants are also included. Furthermore, the server and client devices can be replaced with equivalent cloud services or virtual machines, possibly hosted in a cloud.

The file compressed in FIG. 1 is assumed to be a single unit of compression with respect to the compression algorithm implemented by the compressor 108. In other words, the file is compressed as a single encoding unit, where compression of the last part of the file may depend on the content at the beginning of the file. This is in contrast to a compression approach where a file is sectioned and each section is compressed based only on its own content. Put another way, the compression algorithm is continuously applied to the entire file without being reset. In most cases the compression algorithm will be lossless, but the techniques described herein can also be used with any lossy compression algorithm that has a rolling compression state. The compressor 108 and decompressor 112 are referred to as different elements, but in practice they may by the same module or application where decompression is the inverse function of compression.

As discussed next, rather than download the entire compressed file 102 to obtain the section 106, the compressor 108 can be modified so that compressor state can be captured at different stages of compression or computed on demand for any given position into the compressed stream. If a client only needs a section of the compressed file, then the nearest encompassing part of the compressed file, and a corresponding compressor state, are sent to the client. The client primes its compressor with the compressor state and the primed compressor then decompress the encompassing compressed data without having decompressed whatever compressed data preceded the encompassing compressed data.

FIG. 2 shows how compression checkpoints 120 can be captured while compressing the uncompressed file 110. Before beginning to compress, a modified compressor 108 has no state. The compressor 108 begins compressing the uncompressed file 108. The compressor is configured to periodically capture a checkpoint 120. The period may be based on an amount of uncompressed data that has been processed, an amount of compressed data that has been generated, a compression state (e.g., size of a dictionary), a ratio of the uncompressed file (e.g., 1/100 ), and/or similar measures. The checkpoint rate or basis can be controlled by setting a parameter of the compressor. It is also possible to heuristically bias the checkpoints or granularity based on the content of the file or based on usage data and it is also possible to set the parameter to identify specific areas of interest. Regarding the former, checkpoints can be forced at or near boundaries of elements or data items in the content of the file. Granularity can be increased to match the size of constituent data items. Where the file contains many small data items the checkpoint granularity can be made finer. Where the file contains large data items the checkpoint granularity can be made coarser. Regarding usage data, if there is historic data about what constituent parts of the compressed file are accessed most frequently, then checkpoints can be forced at boundaries of the most frequently accessed constituent parts.

When the compressor 108 determines that the first period has been reached, a first checkpoint 120 is captured. At the least, the checkpoint includes the compressor state 122, denoted S₁ in FIG. 1. The compressor builds its compressor state as it analyzes and compresses the uncompressed data, typically a dictionary. In FIG. 1, state S₁ is the information that the compressor has built (e.g. a dictionary) after compressing the preceding portion of the uncompressed file, which is labeled portion Fu₁ in FIG. 1. The checkpoint 120 may also include an uncompressed file offset 124 (Ou₁) for Fu₁ and a compressed file offset 126 (Oc₁) for the corresponding portion of the compressed file 104. These are distances from the beginning of the respective files. As will be explained below, these offsets can be used to find the compressor state and compressed data that will be needed by the client to decompress any given section or point in the compressed file.

After the first checkpoint is taken compression continues until the next checkpoint is reached. The next checkpoint is captured, which includes the offsets and compressor state up to the current point of compression. The compressor state will likely have changed from the previous compressor state. The compressor state will depend on all of the data that has been compressed already. This process repeats until the entire uncompressed file has been compressed to produce the compressed file 102. The checkpoints 120 are stored as a dataset associated with the compressed file, preferably in the order that they were captured. A checkpoint for the end of the compressed file is not necessary. The checkpoint data will be referred to as random access data 128, as it enables quasi-random access to the compressed data without having to download and decompress all of the preceding compressed data.

In one embodiment, if the uncompressed file is a package or archive that contains discrete elements such as constituent files. In this case, the compressor can also force checkpoints each time a discrete element boundary is reached. These checkpoints can be combined with or used instead of periodic checkpoints. In another embodiment, offsets of constituent elements are captured as encountered but compressor states are only captured periodically.

FIG. 3 shows a process for generating random access data 128. At an initialization step 140 the compressor 108 obtains compression parameters and configures itself with the parameters. The compression parameters may include known parameters such as which algorithm to use, a compression level if applicable, and others. The parameters may also turn checkpointing on or off, set checkpointing parameters such as how often to checkpoint (granularity), specific locations where the checkpoints could take place, or how checkpoints will be marked. While fine-grained granularity is possible, the compression states can be somewhat large relative to the size of the file (e.g., 50 megabytes for a 1 gigabyte file). Too many checkpoints may cause storage and efficiency problems.

After configuring the compressor 108, a compressing step 142 begins. The compressor begins compressing the uncompressed file in the usual manner, accumulating compressor state and outputting compressed data that is an encoding of the so-far-encountered uncompressed data per the compressor state. The compressor state can be any state that is ordinarily produced by a compressor and is retained in some form for use by the compressor at a later stage (and similarly is produced and used by a decompressor). When the compressor determines that a checkpoint has been reached the compressor state and corresponding file offsets are captured. The compressing and checkpointing continue until the uncompressed file has been compressed. At a final step 144 the checkpoints are stored as random access data 128 which can be a suitable object, data structure, or format, for instance a markup file, a table, a Javascript Object Notation file, and so forth. The random access data 128 is stored in association with the compressed file 102 so that when a section of the compressed file is requested the server accesses the correct random access data 128. Alternatively, the checkpoints can be packaged with the compressed file, either in a metadata header or interspersed at the corresponding points in the compressed file.

FIG. 4 shows how the client 100 and the server 104 cooperate to enable the client to download and decompress a minimal amount of compressed file data to obtain a needed section 106. In FIG. 4 the compressed file and random access data are already available on the server before the client needs the section 106. The client begins at step 160 by determining which file and section thereof are needed. The section can be identified by an offset and length (either compressed or uncompressed), or, in the case where the compressed file contains discretely delineated and identified data items, the section can be identified by an identifier of the data item. The indicia of the file and section are then sent to the server in a download request 162.

At step 164 the server receives the download request 162. The server uses the identifier in the request to identify the compressed file and its associated random access data 128. Once the compressed file and random access data 128 are opened or accessible, the server uses the indicia of the section 106 to determine the checkpoint that precedes, and is closest to, the start of the section in the compressed file. If the section 106 is identified by a data item identifier, then the server will use that to identify the start of the section. If the client sent a location of the start of the section in the uncompressed file, then the checkpoint data can be used to find the closest preceding checkpoint. If the client sent a location of the start of the section in the compressed file, then the random access data is searched to find the checkpoint having the largest compressed offset that is smaller than the start of the section in the compressed file.

Once a starting checkpoint has been found, to minimize the amount of compressed data that needs to be sent to the client, the server might also determine an ending checkpoint with a compressed offset that is closest to, but following, the end of the section in the compressed file (which can be provided by the client or inferred by the identity of the section). The ending checkpoint offset can be used by the server to determine an amount of compressed data to send that is both minimal and sufficient for decompressing by the client. Alternatively, the server can send compressed data until the client terminates the transmission.

When the starting offset and amount of compressed data to send (if any) are known, the server sends the client a reply 166 the compressor state of the beginning offset and either or both of the checkpoint's offsets. The server then begins sending the compressed data starting at the compressed offset of the checkpoint. In the example of FIGS. 2 and 4, in the compressed file, the needed section 106 happens to be encompassed within the third compressed portion (Fc₃) of the compressed file. The closest preceding checkpoint is the second checkpoint (Ou₂, Oc₂, S₂). Therefore, the server sends at least the compressor state for the second checkpoint (S₂) and may also send either or both offsets. The server stops sending compressed data when it has sent the previously determined amount of compressed data or when the client ends the transmission.

At step 168 the client receives the compressor state and one or more offsets. The client's decompressor 108 is primed with the compressor state (e.g., S₂). This involves configuring the decompressor with a state that it would have acquired naturally if it had decompressed all of the compressed data that preceded the compressor state's checkpoint in the compressed file. In the example of FIGS. 2 and 4, that would hypothetically be the compressed data from the beginning of the compressed file to the start of Fc₃, i.e., Oc₂.

When the decompressor has been primed, the decompressor begins decompressing the compressed file data from the server. As the decompressor begins decompressing to generate decompressed file data, the client will need to know when it has reached the beginning of the needed section 106 within the decompressed data being outputted by the decompressor. If the section's start is known to the client as an offset from the beginning of the uncompressed file, then the section's start will be a location in the decompressed data chosen such that the amount of decompressed data at that location plus the uncompressed offset from the server (e.g., Ou₂) equals the section's offset within the uncompressed file. Alternatively, the section's start may be identifiable by a pattern of data within the decompressed data, a markup tag, a pattern of data, an identifier that identifies the section, etc. The client continues to receive and decompress data until the end of the section is reached, which can be found in similar fashion. As noted above, the client might signal the server to stop sending data. The client has acquired the needed section 106 by downloading only an internal sub-portion of the compressed data, compressor state, and possibly other information to help identify or extract the section.

FIG. 5 shows a client 100 receiving an internal portion 180 of a compressed file 102, and an associated compressor state 122 and offset 124. First the client, for example executing a web browser operated by a user, obtains and displays a directory listing from the server. The user operates the web browser to select the compressed file 102 from the directory listing. The client then obtains content information such as a manifest, metadata, catalog, an archive/package header, or similar information that lists data items in the compressed file. The user operates the web browser to interactively select, for download, a data item in the compressed file. The web browser sends information to the server that allows the server to identify the data item, for instance an offset and length, an identifier, node in the compressed file that points to the data item, etc.

The server uses the information about the data item to find a checkpoint whose offset most closely precedes the start of the data item. The corresponding compressor state (obtained by compressing the data ahead of the checkpoint) and possibly item-identifying information are sent to the web browser, which primes a decompressor with the compressor state and begins passing it the compressed data from the server, which the decompressor begins decompressing to output the section-containing decompressed file data 182. The item-identifying information might be an offset (and possibly length or ending offset of the data item in the uncompressed data) or a pattern of data within the decompressed data that demarks the data item. In some embodiments, the server does not send any item-identifying information. Instead, the client uses indicia of the data item previously obtained from the server (e.g. a file name, inode identifier, xpath, etc.). When the web browser determines or detects the start of the needed section the web browser begins to save or extract the section to local storage. When the end of the section is determined or detected the section is complete and saved, and the decompressing and downloading are halted.

FIG. 6 shows another embodiment for partial download and decompression. At step 190 the client identifies the file to the server. In this embodiment, at step 192, the server sends the file's random access data to the client. The client then has all of the information it needs to identify needed compressed data to the server. At step 194, in similar manner to previously described server activity, the client determines what section it needs. Based on the section and the random access data, the client determines what compressor state and what portion of the compressed file it will need. The compressor state, already available on the client, is loaded into the client's decompressor. At step 196 the client sends a request to the server for compressed data for the file, specifying a starting offset in the compressed file per the random access data. At step 198 the client receives the compressed data, decompresses with the primed decompressor, and extracts the needed section from the decompressed file data outputted by the decompressor.

The techniques described above can be used with adaptive compression. Adaptive compression involves switching between compression algorithms while compressing the same set of data. When the compressor captures a checkpoint the compressor also includes the compression algorithm with the checkpoint data. When the compressor first switches to a new algorithm, the next checkpoint will include compressor state for that algorithm. The client should not need to be informed of the algorithm switch; the decompressor will automatically switch algorithms based on the content of the compressed data, just as the compressor did.

FIG. 7 shows details of a computing device 300 that may serve as the host 100. The technical disclosures herein will suffice for programmers to write software, and/or configure reconfigurable processing hardware (e.g., field-programmable gate arrays (FPGAs)), and/or design application-specific integrated circuits (ASICs), etc., to run on the computing device 300 to implement any of the features or embodiments described herein.

The computing device 300 may have one or more displays 322, a network interface 324 (or several), as well as storage hardware 326 and processing hardware 328, which may be a combination of any one or more: central processing units, graphics processing units, analog-to-digital converters, bus chips, FPGAs, ASICs, Application-specific Standard Products (ASSPs), or Complex Programmable Logic Devices (CPLDs), etc. The storage hardware 326, which may be local and/or remote, may be any combination of magnetic storage, static memory, volatile memory, non-volatile memory, optically or magnetically readable matter, etc. The meaning of the term “storage”, as used herein does not refer to signals or energy per se, but rather refers to physical apparatuses and states of matter. The hardware elements of the computing device 300 may cooperate in ways well understood in the art of machine computing. In addition, input devices may be integrated with or in communication with the computing device 300. The computing device 300 may have any form-factor or may be used in any type of encompassing device. The computing device 300 may be in the form of a handheld device such as a smartphone, a tablet computer, a gaming device, a server, a rack-mounted or backplaned computer-on-a-board, a system-on-a-chip, or others.

Embodiments and features discussed above can be realized in the form of information stored in volatile or non-volatile computer or device readable storage hardware. This is deemed to include at least hardware such as optical storage (e.g., compact-disk read-only memory (CD-ROM)), magnetic media, flash read-only memory (ROM), or any means of storing digital information in to be readily available for the processing hardware 328. The stored information can be in the form of machine executable instructions (e.g., compiled executable binary code), source code, bytecode, or any other information that can be used to enable or configure computing devices to perform the various embodiments discussed above. This is also considered to include at least volatile memory such as random-access memory (RAM) and/or virtual memory storing information such as central processing unit (CPU) instructions during execution of a program carrying out an embodiment, as well as non-volatile media storing information that allows a program or executable to be loaded and executed. The embodiments and features can be performed on any type of computing device, including portable devices, workstations, servers, mobile wireless devices, and so on.

1. A method performed by a computing device comprising processing hardware and storage hardware, the method comprising:
receiving, from a requesting module, a file identifier and a section identifier, the file identifier identifying a compressed file, the section identifier identifying a section of the compressed file, wherein the section is internal to the compressed file such that there is compressed data between the start of the compressed file and the start of the section within the compressed file;
based on the file identifier, accessing random access data associated with the compressed file, the random access data comprising compression checkpoints captured while compressing an uncompressed file into the compressed file, each compression checkpoint corresponding to a respective location in the compressed file, each compression checkpoint comprising a respective compressor state corresponding to compression up to the checkpoint's location in the compressed file;
based on the section identifier, selecting a checkpoint;
sending, to the module, the compressor state of the selected checkpoint; and
sending, to the module, a portion of the compressed file starting at the location of the selected checkpoint.

2. A method according to claim 1, wherein the module comprises a decompressor, the method further comprising:
receiving, by the module, the compressor state;
configuring the decompressor with the compressor state; and
decompressing, by the configured decompressor, the portion of the compressed file, to output decompressed file data.

3. A method according to claim 2, further comprising extracting the section from the decompressed file data.

4. A method according to claim 1, wherein the checkpoints further comprise respective offsets relative to the start of the compressed file, each offset indicating a position in the compressed file.

5. A method according to claim 4, further comprising selecting based on the offset associated therewith.

6. A method according to claim 5, wherein the checkpoint is selected based on having, among the checkpoints, the offset that is closest to and precedes the section.

7. A method according to claim 1, further comprising ending decompression and/or sending of the portion of the compressed file based on a determination that sufficient file data has been decompressed to recover the section.

8. A method according to claim 1, further comprising compressing the uncompressed file to produce the compressed file, wherein the uncompressed file is compressed as a single unit of compression such that a compressor compressing the uncompressed file evolves a compression dictionary while compressing the entire uncompressed file.

9. A computing device comprising:
processing hardware;
storage hardware storing information configured to cause the processing hardware to perform a process comprising:
identifying a compressed file and an internal section thereof;
sending indicia of the compressed file and the internal section to a server;
receiving, from the server, a compression dictionary and an internal portion of the compressed file that is associated with the compression dictionary, the internal portion containing at least a beginning part of the internal section; and
priming a compressor with the compression dictionary and decompressing the internal portion of the compressed file using the primed compressor.

10. A computing device according to claim 9, wherein the compressed file comprises a compressed archive comprised of constituent files compressed within, and wherein the indicia of the internal section comprises an identifier of a constituent file.

11. A computing device according to claim 9, wherein the computing device comprises a client computing device, wherein the server comprises a server computing device, wherein the indicia of the compressed file and the internal section is sent over a data network to the server, and wherein the compression dictionary and an internal portion of the compressed file are received via the data network.

12. A computing device according to claim 9, wherein the server stores a plurality of compressor states obtained from a compressor, wherein each compressor state was obtained according to compression of all of the uncompressed file data that preceded the compressor state.

13. A computing device according to claim 12, wherein the server selects the compressor state sent to the computing device based on the indicia of the internal section of the compressed file.

14. A computing device according to claim 13, wherein the server selects the compressor state and internal portion based on a location of the internal section in the uncompressed file.

15. A computing device according to claim 9, wherein the indicia of the internal section comprises an identifier thereof, an offset relative to the uncompressed file, or an offset relative to the compressed file.

16. A computing device according to claim 9, wherein the server selects the compressor state and internal portion by finding a file offset closest to the internal section.

17. Computer storage hardware storing information configured to cause one or more computers to perform a process, the process comprising:
receiving, from a client, a request for an internal section of a compressed file;
in response to the request, determining a point in the compressed file that corresponds to the internal section of the compressed file;
obtaining a compressor state that corresponds to the point in the compressed file, the compressor state corresponding to all of the compressed file prior to the point in the compressed file; and
based on the request, sending, to the client, the obtained compressor state and an internal portion of the compressed file that includes the internal section of the compressed file.

18. Computer storage hardware according to claim 17, wherein the compressor state is obtained by, based on the request, performing a compression algorithm on all of the compressed file prior to the point in the compressed file and obtaining the compressor state from the compressor.

19. Computer storage hardware according to claim 18, wherein the compression algorithm is performed responsive to the request.

20. Computer storage hardware according to claim 17, wherein the client decompresses the internal portion of the compressed file using the compressor state and without decompressing any of the compressed file that precedes the internal portion of the compressed file.
